(19) United States
(12) Patent Application Publication
(10) Pub. No.: US 2026/0157043 A1
(43) Pub. Date: Jun. 4, 2026

(54) ORGANIC LIGHT EMITTING DISPLAY APPARATUS

(71) Applicant: LG Display Co., Ltd., Seoul (KR)

(72) Inventors: Miji Song, Paju-si (KR); Yujin Seong, Paju-si (KR)

(73) Assignee: LG Display Co., Ltd., Seoul (KR)

(21) Appl. No.: 19/312,998

(22) Filed: Aug. 28, 2025

(30) Foreign Application Priority Data
Dec. 2, 2024 (KR) 10-2024-0176288

(51) Int. Cl. H10K 59/122; H10K 59/80; H10K 102/00

(52) U.S. Cl. CPC H10K 59/122; H10K 59/80515; H10K 59/873; H10K 2102/351

(57) ABSTRACT

An organic light emitting display apparatus includes a substrate having a plurality of subpixels; an anode electrode on the substrate in one of the plurality of subpixels; a first bank layer on the substrate and having a first opening exposing the anode electrode; and a second bank layer on the first bank layer and having a second opening wider than the first opening, wherein the second bank layer includes a first region and a second region thinner than the first region, and wherein the second region has a shape that protrudes in a direction away from the anode electrode in a plan view.

### CROSS-REFERENCE TO RELATED APPLICATION

This application claims the benefit of priority of Korean Patent Application No. 10-2024-0176288, filed on Nov. 2, 2024, which is hereby incorporated by reference as if fully set forth herein.

### BACKGROUND

### Field of the Disclosure

The present disclosure relates to an organic light emitting display apparatus.

### Discussion of the Related Art

As the information society develops, interest in display apparatuses for displaying images and the demand for using them are increasing in various forms, and the display field has been developing rapidly. In response, various lightweight and thin flat panel display apparatuses have been developed and are receiving attention. Recently, display apparatuses, such as liquid crystal display apparatuses and organic light emitting display apparatuses, are being utilized.

Organic light emitting display apparatuses are self-luminous display apparatuses that display images on a display panel by emitting light from an organic light emitting layer sandwiched between two electrodes. Unlike liquid crystal displays, they do not require a separate light source, such as a backlight unit, and thus can be manufactured in a lightweight and thin form. In addition, organic light emitting display apparatuses are advantageous in terms of power consumption due to low-voltage operation, and are also excellent in color expression, response speed, viewing angle, and contrast ratio.

An organic light emitting display apparatus includes pixels, each pixel including an organic light emitting element, and a bank layer that partitions the pixels to define the pixels. The bank layer can serve as a pixel defining film.

As the design of pixels changes from square to circular, the organic film spreads, resulting in defects in which the organic film is not applied. Recently, research is being continuously conducted to improve the spreadability of the organic film.

### SUMMARY

Accordingly, the present disclosure is directed to an organic light emitting display apparatus that substantially obviates ones or more problems due to limitations and disadvantages of the related art.

Example embodiments of the present disclosure provide an organic light emitting display apparatus in which the spreadability of an organic film is improved by controlling the shape of a bank layer.

Additional advantages and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the present disclosure, as embodied and broadly described herein, an organic light emitting display apparatus includes a substrate having a plurality of subpixels; an anode electrode on the substrate in one of the plurality of subpixels; a first bank layer on the substrate and having a first opening exposing the anode electrode; and a second bank layer on the first bank layer and having a second opening wider than the first opening, wherein the second bank layer includes a first region and a second region thinner than the first region, and wherein the second region has a shape that protrudes in a direction away from the anode electrode in a plan view.

The second bank layer may include a third region disposed closer to the anode electrode than the second region in the plan view, and the third region may have a smaller thickness than the second region.

The anode electrode may have a circular or elliptical shape in the plan view, the third region may have a ring shape surrounding the anode electrode in the plan view, and the second region may have a shape protruding from the third region away from the anode electrode in the plan view.

The third region may be positioned between the anode electrode and the first region in the plan view.

The second region and the third region may each include an inclined surface and be formed by patterning.

The second region may include a first portion and a second portion spaced apart from each other, and the first portion and the second portion of the second region may protrude in different directions from each other with respect to the anode electrode in the plan view.

The second bank layer may include a micro-protrusion region protruding from the second region in the plan view, and the micro-protrusion region may have a same thickness as the second region.

At least a portion of the first bank layer may not overlap the second bank layer in the plan view.

The portion of the first bank layer not overlapping with the second bank layer may have a shape of a circular ring or an elliptical ring around the anode electrode in the plan view.

The anode electrode may be disposed in the first opening and the second opening in the plan view.

The organic light emitting display apparatus may further include an organic film on the second bank layer, wherein the organic film may be disposed in the first opening and the second opening and may cover a side surface and an upper surface of the second bank layer.

Each of the first opening and the second opening may have a circular or elliptical shape.

The first bank layer may be a black bank layer, and the second bank layer may be a transparent bank layer.

The second region may have a spearhead shape with a decreasing width in the direction away from the anode electrode in the plan view.

The second bank layer includes a micro-protrusion region having a shape that protrudes from the second region and narrows in width in a direction away from the second region in the plan view.

In another aspect of the present disclosure, a light emitting display apparatus includes a substrate having a subpixel; an anode electrode on the substrate in the subpixel; a bank layer on the substrate and having an opening exposing the anode electrode, the bank layer having a first region and a second region thinner than the first region, wherein the second region of the bank layer may have a shape that protrudes in a direction away from the anode electrode in a plan view.

The second region of the bank layer may have a first portion and a second portion protruding away from the anode electrode in different directions from each other in the plan view.

The first portion and the second portion of the second region of the bank layer may be spaced apart from each other with the first region of the bank layer disposed between the first portion and the second portion of the second region in the plan view. The first region of the bank layer may surround the second region of the bank layer in the plan view.

The second region of the bank layer may have a spearhead shape with a decreasing width in the direction away from the anode electrode in the plan view.

The light emitting display apparatus may further include: an organic film on the bank layer and the anode electrode; and another bank layer between the substrate and the bank layer, the other bank layer having an opening that exposes the anode electrode and has a smaller width than the opening of the bank layer, wherein the organic film may cover the first region and the second region of the bank layer and fill the opening of the bank layer and the opening of the other bank layer, and wherein each of the opening of the bank layer and the opening of the other bank layer may have a circular or elliptical shape in the plan view.

It is to be understood that both the foregoing general description and the following detailed description are by way of example and are intended to provide further explanation of the disclosure as claimed.

### BRIEF DESCRIPTION OF THE DRAWINGS

The accompanying drawings, which are included to provide a further understanding of the present disclosure and are incorporated in and constitute a part of this application, illustrate example embodiments of the present disclosure and together with the description serve to explain various principles of the present disclosure.

FIG. 1 is a drawing for explaining an organic light emitting display apparatus according to an example embodiment of the present disclosure.

FIG. 2 is a perspective view showing a portion of a display area of a display panel according to an example embodiment of the present disclosure.

FIG. 3 is an enlarged plan view of a portion of a display area of a display panel according to an example embodiment of the present disclosure.

FIG. 4 is a cross-sectional view taken along line I-I′ in FIG. 3.

FIG. 5 is a cross-sectional view of a portion of a display area of a display panel according to another example embodiment of the present disclosure.

FIG. 6 is a cross-sectional view taken along line II-II′ in FIG. 3.

FIG. 7 is an enlarged plan view of a portion of a display area of a display panel according to another example embodiment of the present disclosure.

FIG. 8 is a cross-sectional view taken along line III-III′ in FIG. 7.

### DETAILED DESCRIPTION

Advantages and features of the present disclosure and implementation methods thereof will be clarified through following example embodiments described with reference to the accompanying drawings. The present disclosure may, however, be embodied in different forms and should not be construed as limited to the embodiments set forth herein. Rather, these example embodiments are provided so that this disclosure will be thorough and complete and will fully convey the scope of the present disclosure to those skilled in the art. Further, the protected scope of the present disclosure may be defined by the claims and their equvalients.

A shape, a size, a ratio, an angle, and a number disclosed in the drawings for describing example embodiments of the present disclosure are merely an example. Thus, the present disclosure is not limited to the illustrated details. Like reference numerals refer to like elements throughout the specification, unless otherwise specified. In the following description, where the detailed description of the relevant known function or configuration may unnecessarily obscure features of the present disclosure, the detailed description of such known function or configuration may be omitted.

In a case where terms like “comprise, ,” “have,” and “include” are used in describing the present disclosure, another portion or element may be added unless a more limiting term like “only˜” is used. The terms of a singular form may include plural forms, and vice versa, unless referred to the contrary.

In construing an element, the element should be construed as including an error band although there is no explicit description.

In describing a position relationship, for example, where the position relationship between two portions is described as “upon˜,” “above˜,: “below˜,” and “next to˜,” one or more portions may be disposed between the two portions unless a more limiting term like “just” or “direct” is used.

Spatially relative terms such as “below,” “beneath,” “lower,” “above,” and “upper” may be used herein to describe a relationship of one element or elements to another element or elements as illustrated in the drawings. It should be understood that these terms are intended to encompass different orientations of the device in addition to the orientation depicted in the drawings. For example, if the device illustrated in the figure is reversed, the device described to be arranged “below” or “beneath” one other device may be arranged “above” the other device. Therefore, an example term “below or beneath” may include “below or beneath” and “above” orientations. Likewise, an example term “above” or “on” may include “above” and “below or beneath” orientations.

In describing a temporal relationship, for example, where the temporal order is described as “after,” “subsequent,” “next,” and “before,” a case which is not continuous may be included, unless a more limiting term like “just” or “direct” is used.

It should be understood that, although the terms “first,” “second,” etc., may be used herein to describe various elements, these elements should not be limited by these terms. These terms are only used to refer to one element separately from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element, and a third element” may include all combinations of two or more elements selected from the first, second and third elements, as well as each of the first, second and third elements.

Features of various embodiments of the present disclosure may be partially or wholly coupled to or combined with each other and may be variously inter-operated with each other and driven technically as those skilled in the art can sufficiently understand. The embodiments of the present disclosure may be carried out independently from each other or may be carried out together in a co-dependent relationship.

In the addition of reference numerals to the components of each drawing describing embodiments of the present disclosure, the same components can have the same sign as can be displayed on the other drawings.

Reference will now be made in detail to various embodiments of the present disclosure, examples of which are illustrated in the accompanying drawings.

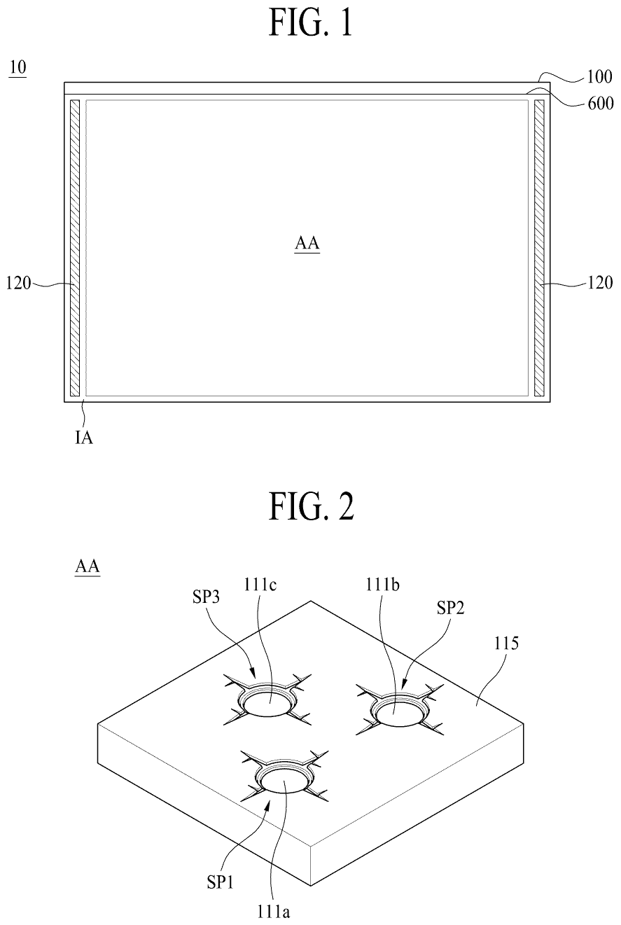

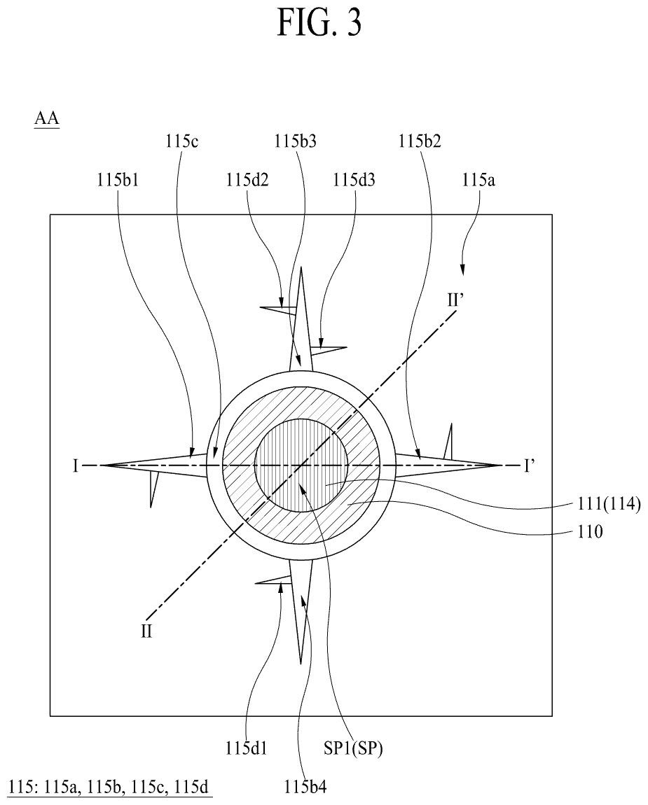

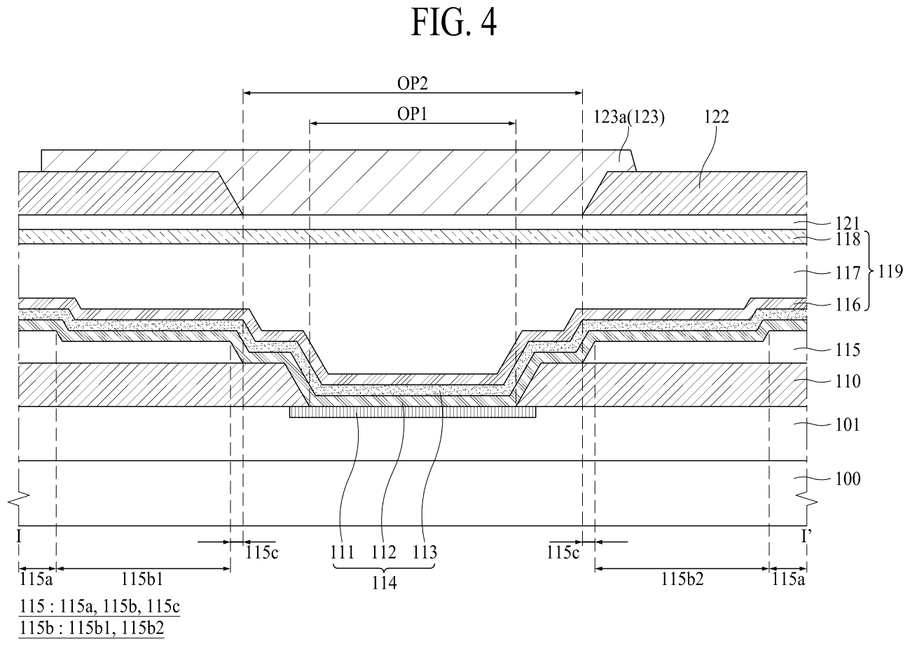

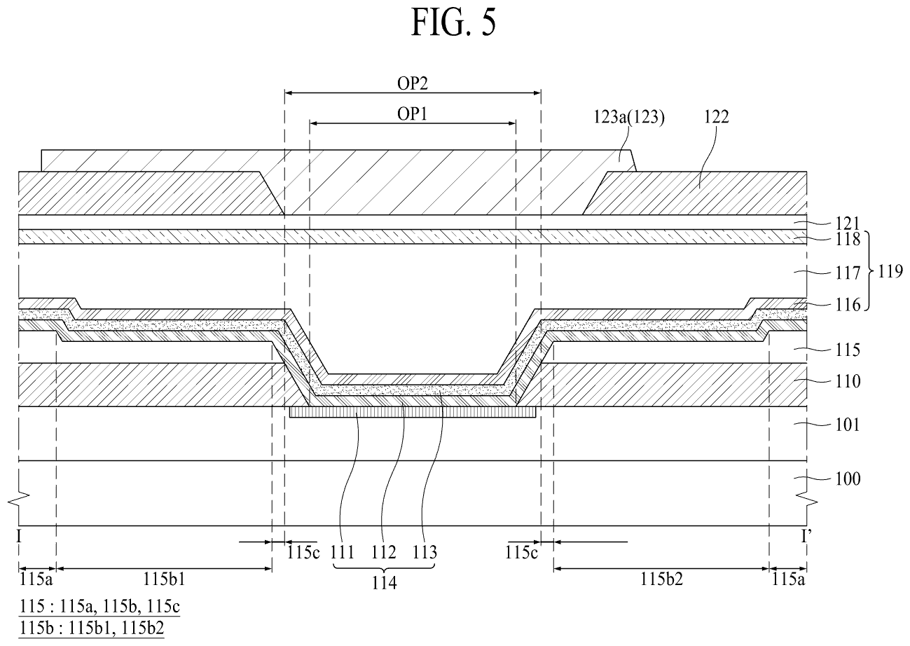

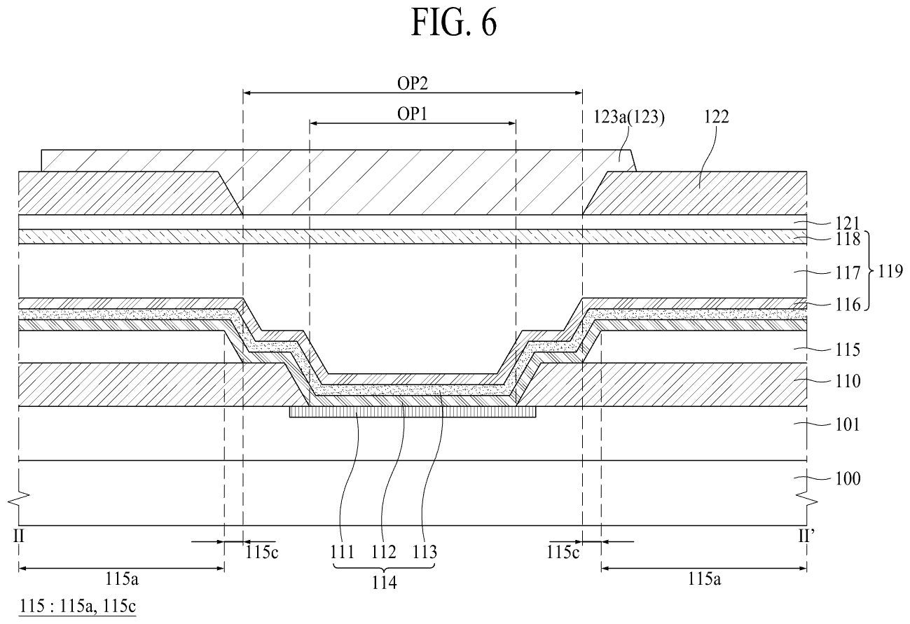

FIG. 1 is a drawing for explaining an organic light emitting display apparatus according to an example embodiment of the present disclosure. FIG. 2 is a perspective view showing a part of a display area (AA) of a display panel (10) according to an example embodiment of the present disclosure. FIG. 3 is an enlarged plan view of a part of a display area (AA) of a display panel (10) according to an example embodiment of the present disclosure. FIG. 4 is a cross-sectional view taken along line I-I′ in FIG. 3. FIG. 5 is a cross-sectional view of a part of a display area (AA) of a display panel (10) according to another example embodiment of the present disclosure. FIG. 6 is a cross-sectional view taken along line II-II′ in FIG. 3.

As illustrated in FIG. 1, an organic light emitting display apparatus according to an example embodiment of the present disclosure may include a display panel (10) including a substrate (100) and a counter substrate (600) bonded to each other.

The substrate (100) may be a transparent glass substrate or a transparent plastic substrate. The substrate (100) may include a display area (AA) and a non-display area (IA).

The display area (AA) is an area where an image is displayed, and may be a pixel array area, an active area, a pixel array unit, a display unit, or a screen. The display area (AA) may include a plurality of pixels.

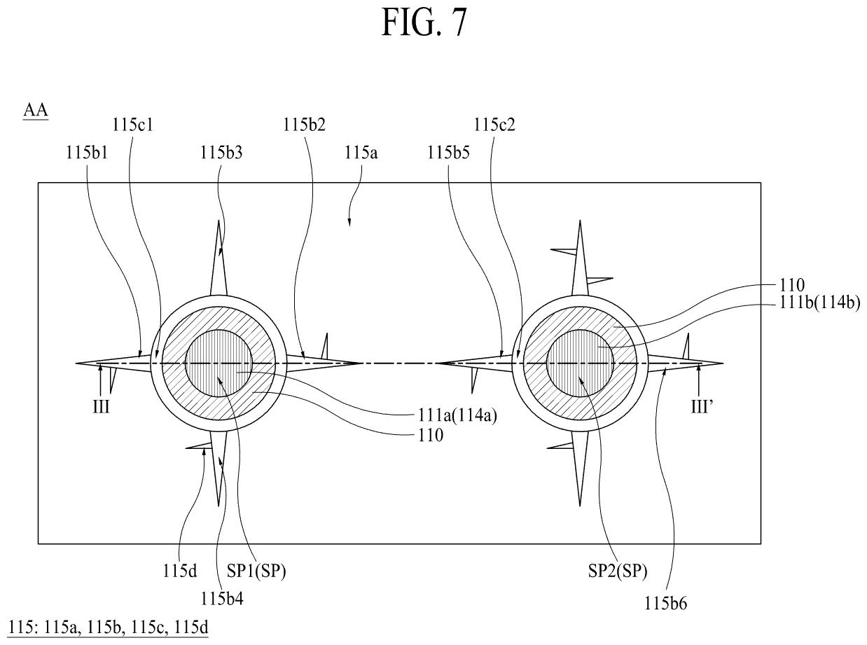

Each of the plurality of pixels may include a plurality of subpixels (SP). For example, the plurality of subpixels (SP) may constitute a plurality of pixels. For example, the plurality of subpixels (SP) may include a first subpixel (SP1) and a second subpixel (SP2) (see, e.g., FIG. 7). In other words, the substrate (100) may include a plurality of subpixels (SP).

The non-display area (IA) is an area where an image is not displayed, and may be a peripheral circuit area, a signal supply area, an inactive area, or a bezel area. The non-display area (IA) may be configured to surround the display area (AA). The display panel (10) or the substrate (100) may further include a peripheral circuit unit (120) disposed in the non-display area (IA). The peripheral circuit unit (120) may include a gate driving circuit connected to a plurality of subpixels (SP).

The counter substrate (600) may be configured to overlap the display area (AA). The counter substrate (600) may be bonded to the substrate (100) by using an adhesive (or transparent adhesive) to face the substrate (100) or may be disposed in such a way that an organic or inorganic material is laminated on the substrate (100). The counter substrate (600) may be an upper substrate, a second substrate, or an encapsulating substrate, and may correspond to encapsulating the substrate (100).

As shown in FIG. 2, an organic light emitting display apparatus or display panel (10) according to an example embodiment of the present disclosure may include a plurality of subpixels (SP). FIG. 2 illustrates a display panel (10) including a first subpixel (SP1), a second subpixel (SP2), and a third subpixel (SP3) among a plurality of subpixels (SP).

For example, each of the plurality of pixels may include a first red subpixel (SP1), a second green subpixel (SP2), and a third blue subpixel (SP3). However, the present disclosure is not limited thereto. Each of the first to third subpixels (SP1 to SP3) may be configured to have different sizes (or areas). FIG. 3 illustrates a display panel (10) including a first subpixel (SP1) among the plurality of subpixels (SP), and FIG. 7 illustrates a display panel (10) including a first subpixel (SP1) and a second subpixel (SP2) among the plurality of subpixels (SP).

As illustrated in FIG. 2, the first subpixel (SP1), the second subpixel (SP2), and the third subpixel (SP3) may include a first anode electrode (111a), a second anode electrode (111b), and a third anode electrode (111c), respectively.

FIG. 2 is a drawing schematically showing the shape of the second bank layer (115). Specifically, FIG. 2 shows a shape in which the second bank layer (115) has a step and a width that narrows in a direction away from a corresponding one of the first anode electrode (111a), the second anode electrode (111b), and the third anode electrode (111c). A more detailed description of the second bank layer (115) is described below.

As shown in FIGS. 3, 4, 5, and 6, the organic light emitting display apparatus may include an anode electrode (111), a first bank layer (110), a second bank layer (115), and an organic film (117).

The components of an organic light emitting display apparatus are described in detail below.

A detailed description of the substrate (100) is omitted here as it overlaps with the content described in FIG. 1.

A circuit element layer (101) may be disposed on a substrate (100). The circuit element layer (101) may include a buffer layer, at least one thin film transistor, insulating layers, a capacitor, and various wirings.

The buffer layer has insulating properties and protects the active layer of the thin film transistor. The buffer layer may include at least one of silicon oxide (SiOx), silicon nitride (SiNx), and a metal oxide having insulating properties.

The thin film transistors can be disposed on a buffer layer. The thin film transistor includes an active layer, a gate electrode, a source electrode, and a drain electrode.

The thin film transistor can include one or more of a switching thin film transistor, a driving thin film transistor, and a sensing thin film transistor.

The switching thin film transistor is configured to be switched according to the gate signal supplied to the gate wiring and supplies the data voltage supplied from the data wiring to the driving thin film transistor.

The driving thin film transistor is configured to be switched according to the data voltage supplied from the switching thin film transistor, to generate a data current from the power supplied from the power wiring, and to supply it to the anode electrode (111) of the organic light emitting element (114).

The sensing thin film transistor is configured to sense the threshold voltage deviation of the driving thin film transistor, which can cause image quality deterioration, and to supply current from the driving thin film transistor to the reference wiring in response to a sensing control signal supplied from the gate wiring or a separate sensing wiring.

Insulating layers may be disposed on the thin film transistor. The insulating layers are for insulating the thin film transistor. The insulating layers may be formed of an inorganic film, such as a silicon oxide film (SiOx), a silicon nitride film (SiNx), or a multilayer thereof.

The capacitor serves to maintain the data voltage supplied to the driving thin film transistor for one frame, and is connected to the gate electrode and source electrode of the driving thin film transistor, respectively.

Various wires may be disposed on the insulating layers. Various wires may also be connected to the thin film transistors by penetrating the insulating layers.

The organic light emitting element (114) may include an anode electrode (111), an organic light emitting layer (112), and a cathode electrode (113). The anode electrode (111) may be a first electrode or a pixel electrode, and the cathode electrode (113) may be a second electrode or a common electrode.

The anode electrode (111) may be disposed on the circuit element layer (101). The anode electrode (111) may be a transparent electrode, a semi-transparent electrode, or a reflective electrode. The anode electrode (111) may include a single layer or a multilayer structure. According to an example embodiment of the present disclosure, the anode electrode (111) may be formed by being patterned.

The organic light emitting layer (112) may be disposed on the anode electrode (111). The organic light emitting layer (112) may include a light emitting layer including a light emitting material. The organic light emitting layer (112) may further include a hole injection layer (HIL) and a hole transport layer (HTL) disposed between the anode electrode (111) and the light emitting layer, and may further include an electron transport layer (ETL) and an electron transport layer (EIL) disposed on the light emitting layer.

According to an example embodiment of the present disclosure, the organic light emitting layer (112) can cover the side surface of the first bank layer (110) and cover the side surface and the upper surface of the second bank layer (115). Specifically, the organic light emitting layer (112) can be in contact with a part of the side surface and the upper surface of the first bank layer (110) and in contact with the side surface and the upper surface of the second bank layer (115) (see, e.g., FIG. 4).

The cathode electrode (113) may be disposed on the organic light emitting layer (112). The cathode electrode (113) may be formed of a transparent metal material (TCO) such as ITO or IZO that can transmit light, or a semitransparent metal material such as magnesium (Mg), silver (Ag), or an alloy of magnesium (Mg) and silver (Ag).

According to an example embodiment of the present disclosure, the cathode electrode (113) can cover the side surface of the first bank layer (110) and cover the side surface and upper surface of the second bank layer (115). Specifically, the cathode electrode (113) can cover the side surface of the first bank layer (110) and cover the side surface and upper surface of the second bank layer (115) with the organic light emitting layer (112) interposed therebetween (see, e.g., FIG. 4).

The first bank layer (110) may be disposed on the circuit element layer (101). A first opening (OP1) may be defined by the first bank layer (110). The first opening (OP1) may correspond to the anode electrode (111) and may expose a part of the anode electrode (111). Specifically, the first bank layer (110) may be disposed on the anode electrode (111). More specifically, the first bank layer (110) may cover an end of the anode electrode (111).

The first bank layer (110) may be a black bank layer or a transparent bank layer. For example, the black bank layer may be formed of at least one of an organic insulating material, such as black resin, graphite powder, graphite ink, black spray, and black enamel. The transparent bank layer may be formed by applying a photosensitive organic insulating material and then patterning it. Preferably, the first bank layer (110) may be a black bank layer.

The second bank layer (115) may be disposed on the first bank layer (110). A second opening (OP2) may be defined by the second bank layer (115). According to an example embodiment of the present disclosure, the second opening (OP2) may have a greater width than the first opening (OP1). For example, the second opening (OP2) may have a wider area than the first opening (OP1).

The second bank layer (115) may be a transparent bank layer. For example, the second bank layer (115) may be formed by applying a photosensitive organic insulating material and then patterning it.

According to an example embodiment of the present disclosure, the organic light emitting display apparatus may have a two-layer structure of a first bank layer (110) and a second bank layer (115). Here, the first bank layer (110) may preferably be positioned at a lower layer so as to minimize contact with the organic light emitting layer (112), and the second bank layer (115) may preferably be positioned on the first bank layer (110). In other words, the second bank layer (115), which is a transparent bank layer, may cover the first bank layer (110), which is a black bank layer, thereby preventing contact between the first bank layer (110) and the organic light emitting layer (112).

In general, the black bank layer has higher outgassing than the transparent bank layer, and the barrier effect of blocking the outgassing is also lower in the black bank layer than in the transparent bank layer. According to an example embodiment of the present disclosure, by forming the second bank layer (115), which is a transparent bank layer, on the first bank layer (110), which is a black bank layer, the outgassing that may occur when forming the black bank can be reduced, and the generation of impurities that may occur when heat-treating the black bank can also be reduced.

In addition, by forming the first bank layer (110), which is a black bank layer, under the second bank layer (115), which is a transparent bank layer, it is possible to implement a high-brightness organic light emitting display apparatus while preventing or reducing light leakage.

According to an example embodiment of the present disclosure, the second bank layer (115) may include a first region (115a), a second region (115b), and a third region (115c).

As illustrated in FIGS. 3 and 4, the second bank layer (115) may include a first region (115a), a second region (115b) that is thinner than the first region (115a), and a third region (115c) that is thinner than the first region (115a) and the second region (115b). For example, the second region (115b) and the third region (115c) refer to regions that are formed by being patterned compared to the first region (115a). Specifically, the second region (115b) and the third region (115c) refer to regions that are formed by being only partially patterned compared to the first region (115a).

According to an example embodiment of the present disclosure, the first region (115a), the second region (115b), and the third region (115c) of the second bank layer (115) can be disposed on the first bank layer (110).

According to an example embodiment of the present disclosure, the second region (115b) may have a shape that protrudes in a direction away from the anode electrode (111) in a plane. For example, FIG. 3 illustrates a shape in which the second region (115b) protrudes in a direction away from the anode electrode (111). For example, a first portion (115b1) and a second portion (115b2) of the second region (115b) may each protrude in different directions from each other. Specifically, the first portion of the second region (115b1) may protrude in a plane toward the left side of the anode electrode (111), and the second portion of the second region (115b2) may protrude in a plane toward the right side of the anode electrode (111). The present disclosure is not limited thereto, and the second region (115b) may further include a third portion (115b3) and a fourth portion (115b4). Here, the first portion of the second region (115b1), the second portion of the second region (115b2), the third portion of the second region (115b3), and the fourth portion of the second region (115b4) can each protrude in different directions from one another.

For example, the second region (115b) may be narrowed in width in a direction away from the anode electrode (111) in a plane.

According to an example embodiment of the present disclosure, the second region (115b) and the third region (115c) may each include an inclined region. Specifically, the inclined surface of each of the second region (115b) and the third region (115c) may face the anode electrode (111).

According to an example embodiment of the present disclosure, the third region (115c) may be disposed closer to the anode electrode (111) in a plane compared to the second region (115b). For example, the anode electrode (111) may have a circular or elliptical shape in a plane, and the third region (115c) may have a ring shape surrounding the anode electrode (111) in a plane. In this case, the second region (115b) may have a triangular spearhead shape that protrudes from the third region (115c).

According to an example embodiment of the present disclosure, the first region (115a) may mean a region in the second bank layer (115) excluding the second region (115b) and the third region (115c). For example, the first region (115a) may mean a region that is not etched or patterned. In addition, the first region (115a) may be a region having the largest thickness in the second bank layer (115).

As shown in FIGS. 3 and 4, the first region (115a) can surround the second region (115b) and the third region (115c).

According to an example embodiment of the present disclosure, the third region (115c) may be disposed between the anode electrode (111) and the first region (115a) in a plane. Specifically, as illustrated in FIG. 3, at least a portion of the first bank layer (110) may be disposed between the anode electrode (111) and the third region (115c) in a plane.

According to an example embodiment of the present disclosure, an encapsulation layer (119) may be disposed on the second bank layer (115). The encapsulation layer (119) may have a structure in which a first inorganic film (116), an organic film (117), and a second inorganic film (118) are intersected and laminated.

The encapsulation layer (119) serves to prevent or suppress oxygen or moisture from penetrating into the cathode electrode (113). To this end, the encapsulation layer (119) may include a first inorganic film (116) and a second inorganic film (118). The first inorganic film (116) and the second inorganic film (118) may each be formed of silicon nitride, aluminum nitride, zirconium nitride, titanium nitride, hafnium nitride, tantalum nitride, silicon oxide, aluminum oxide, or titanium oxide.

The organic film (117) can be formed to a sufficient thickness to prevent particles from penetrating the encapsulation layer (119) and entering the organic light emitting layer (112) and the cathode electrode (113).

According to an example embodiment of the present disclosure, the organic film (117) may be formed transparently to transmit light emitted from the organic light emitting layer (112). The organic film (117) may be formed of an organic material capable of transmitting 99% or more of light emitted from the organic light emitting layer (112), such as an acrylic resin, an epoxy resin, a phenolic resin, a polyamide resin, or a polyimide resin. The organic film (117) may be formed by an ink-jet process. However, the present disclosure is not limited thereto.

Recently, as the design of pixels has changed from polygonal to circular or elliptical shapes, a problem has arisen in which the organic material of the organic film formed by the ink-jet process spreads along the circumference of the pixel. For example, when the pixels have a circular shape, the organic material of the organic film is disposed adjacent to the edge of the circular pixel and the spreading property is weakened, resulting in a defect in which the organic film is not applied to the center of the circular pixel. As a result, moisture and oxygen from the external environment may penetrate into the light emitting element, which may deteriorate the electrical performance of the display and shorten its lifespan.

According to an example embodiment of the present disclosure, since the second bank layer (115) includes a second region (115b) that protrudes in a direction away from the anode electrode (111) in a plane, the capillary phenomenon can be improved around the anode electrode (111), and the spreadability of the organic film (117) can be increased. As a result, the potential defect of the organic film (117) not being applied can be prevented or suppressed, and the organic film (117) can be filled in the center of the anode electrode (111) in a plane.

According to an example embodiment of the present disclosure, the second bank layer (115) may include a micro-protrusion region (115d) that protrudes from the second region (115b) in a plane. Here, the micro-protrusion region (115d) may have the same thickness as the second region (115b).

According to an example embodiment of the present disclosure, the micro-protrusion region (115d) may include a plurality of sub-micro-protrusion regions (115d1, 115d2, 115d3, etc.). For example, as shown in FIG. 3, the first sub-micro-protrusion region (115d1) protrudes from the fourth portion of the second region (115b4), and the second sub-micro-protrusion region (115d2) and the third sub-micro-protrusion region (115d3) protrude from the third portion of the second region (115b3). However, the present disclosure is not limited thereto, and three or more sub-micro-protrusion regions may protrude from the second region (115b) in a plane.

For example, the micro-protrusion region (115d) may have a triangular spearhead shape that protrudes from the second region (115b) and narrows in width in a direction away from the second region (115b) in a plane.

According to an example embodiment of the present disclosure, as the micro-protrusion region (115d) is disposed, the capillary phenomenon can be maximized or increased around the anode electrode (111). As a result, the potential defect of the organic film (117) not being applied can be further suppressed, and the organic film (117) can be filled toward the anode electrode (111) in a plane.

According to an example embodiment of the present disclosure, at least a portion of the first bank layer (110) may not overlap with the second bank layer (115). For example, as shown in FIG. 3, a region of the first bank layer (110) that does not overlap with the second bank layer (115) may have a shape of a circular ring or an elliptical ring in a plan view.

According to an example embodiment of the present disclosure, the organic film (117) may be disposed within the first opening (OP1) and the second opening (OP2). Specifically, the organic film (117) may cover the side and upper surface of the second bank layer (115). FIG. 4 illustrates an example in which the organic film (117) is filled within the first opening (OP1) and the second opening (OP2).

According to an example embodiment of the present disclosure, the anode electrode (111) may be disposed in the first opening (OP1) and the second opening (OP2) in a plane. According to an example embodiment of the present disclosure, a part of the anode electrode (111) may be disposed outside the first opening (OP1). Specifically, a part of the anode electrode (111) may be covered by an end of the first bank layer (110).

According to an example embodiment of the present disclosure, the first opening (OP1) and the second opening (OP2) may each have a circular or elliptical shape (see, e.g., FIGS. 3 and 4).

According to an example embodiment of the present disclosure, an upper buffer layer (121) may be disposed on the encapsulation layer (119). The upper buffer layer (121) may be formed of an organic insulating material having a low dielectric constant. For example, the upper buffer layer (121) may include an acrylic resin, an epoxy resin, or a siloxane resin. The upper buffer layer (121) may be formed of an inorganic insulating material and may be disposed over the entire upper surface of the encapsulation layer (119).

According to an example embodiment of the present disclosure, a black matrix (122) and color filter layers (123) may be disposed on the upper buffer layer (121).

The black matrix (122) may be disposed between color filter layers (123) to prevent light from one pixel from traveling to the color filter layer of an adjacent pixel and causing color mixing. In addition, the black matrix (122) may be disposed to overlap with the first bank layer (110) corresponding to a non-light emitting portion.

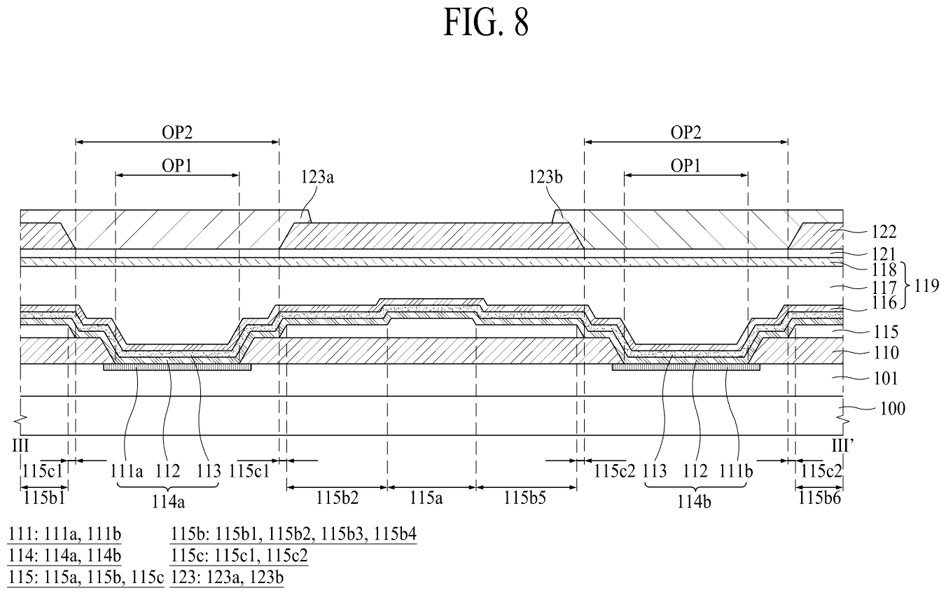

Each of the color filter layers (123) may be disposed to correspond to a plurality of subpixels (SP). For example, as shown in FIGS. 7 and 8, the first color filter layer (123a) may be disposed to correspond to the first subpixel (SP1), and the second color filter layer (123b) may be disposed to correspond to the second subpixel (SP2).

As illustrated in FIG. 5, compared to FIG. 4, the second bank layer (115) can be etched simultaneously with the first bank layer (110). According to FIG. 4, the second bank layer (115) can be etched by a different process from the first bank layer (110). For example, as shown in FIG. 4, the second bank layer (115) can expose the flat top surface of the first bank layer (110). As shown in FIG. 5, the second bank layer (115) may not expose the flat top surface of the first bank layer (110).

FIG. 7 is an enlarged plan view of a portion of a display area (AA) of a display panel according to another example embodiment of the present disclosure. FIG. 8 is a cross-sectional view taken along line III-III′ in FIG. 7.

As illustrated in FIGS. 7 and 8, the plurality of subpixels (SP) may include a first subpixel (SP1) and a second subpixel (SP2). The description of the first subpixel (SP1) and the second subpixel (SP2) overlaps with the description of the first subpixel (SP1) illustrated in FIG. 3.

For example, as shown in FIGS. 7 and 8, a first organic light emitting element (114a) is disposed in a first subpixel (SP1), and a second organic light emitting element (114b) is disposed in a second subpixel (SP2). The first organic light emitting element (114a) includes a first anode electrode (111a), and the second organic light emitting element (114b) includes a second anode electrode (111b).

The second region of the second bank layer (115b) may include a fifth portion (115b5) and a sixth portion (115b6) disposed in the second subpixel (SP2). The second region of the second bank layer (115b) may further include a seventh portion and an eighth portion disposed in the second subpixel (SP2). The fifth portion of the second region (115b5) and the sixth portion of the second region (115b6) may correspond to the first portion of the second region (115b1) and the second portion of second region (115b2) disposed in the first subpixel (SP1), respectively.

The third region of the second bank layer (115c) may include a first portion (115c1) disposed in the first subpixel (SP1) and a second portion (115c2) disposed in the second subpixel (SP2).

According to an example embodiment of the present disclosure, the first portion of the third region (115c1) illustrated in FIGS. 7 and 8 may correspond to the third region (115c) illustrated in FIGS. 1 to 6. The description of the second portion of the third region (115c2) is omitted as it overlaps with the description of the first portion of the third region (115c1).

As illustrated in FIGS. 7 and 8, the first color filter layer (123a) and the second color filter layer (123b) may be disposed in the first subpixel (SP1) and the second subpixel (SP2), respectively.

It will be apparent to those skilled in the art that the present disclosure described above is not limited by the above-described embodiments and the accompanying drawings and that various substitutions, modifications and variations can be made in the present disclosure without departing from the spirit or scope of the disclosures. Consequently, the protected scope of the present disclosure may be defined by the accompanying claims and their equivalents, and it is intended that all variations or modifications derived from the meaning, scope, and equivalent concept of the claims fall within the scope of the present disclosure.

What is claimed is:

1. An organic light emitting display apparatus, comprising:
a substrate having a plurality of subpixels;
an anode electrode on the substrate in one of the plurality of subpixels;
a first bank layer on the substrate and having a first opening exposing the anode electrode; and
a second bank layer on the first bank layer and having a second opening wider than the first opening,
wherein the second bank layer includes:
a first region; and
a second region thinner than the first region, and
wherein the second region has a shape that protrudes in a direction away from the anode electrode in a plan view.

2. The organic light emitting display apparatus of claim 1, wherein the second bank layer includes a third region disposed closer to the anode electrode than the second region in the plan view, and the third region has a smaller thickness than the second region.

3. The organic light emitting display apparatus of claim 2, wherein the anode electrode has a circular or elliptical shape in the plan view,
wherein the third region has a ring shape surrounding the anode electrode in the plan view, and
wherein the second region has a shape protruding from the third region away from the anode electrode in the plan view.

4. The organic light emitting display apparatus of claim 2, wherein the third region is positioned between the anode electrode and the first region in the plan view.

5. The organic light emitting display apparatus of claim 2, wherein the second region and the third region each include an inclined surface and are formed by patterning.

6. The organic light emitting display apparatus of claim 1, wherein the second region includes a first portion and a second portion spaced apart from each other, and
wherein the first portion and the second portion of the second region protrude in different directions from each other with respect to the anode electrode in the plan view.

7. The organic light emitting display apparatus of claim 1, wherein the second bank layer includes a micro-protrusion region protruding from the second region in the plan view, and
wherein the micro-protrusion region has a same thickness as the second region.

8. The organic light emitting display apparatus of claim 1, wherein at least a portion of the first bank layer does not overlap the second bank layer in the plan view.

9. The organic light emitting display apparatus of claim 8, wherein the portion of the first bank layer not overlapping with the second bank layer has a shape of a circular ring or an elliptical ring around the anode electrode in the plan view.

10. The organic light emitting display apparatus of claim 1, wherein the anode electrode is disposed in the first opening and the second opening in the plan view.

11. The organic light emitting display apparatus of claim 1, further comprising an organic film on the second bank layer,
wherein the organic film is disposed within the first opening and the second opening and covers a side surface and an upper surface of the second bank layer.

12. The organic light emitting display apparatus of claim 1, wherein each of the first opening and the second opening has a circular or elliptical shape.

13. The organic light emitting display apparatus of claim 1, wherein the first bank layer is a black bank layer, and the second bank layer is a transparent bank layer.

14. The organic light emitting display apparatus of claim 1, wherein the second region has a spearhead shape with a decreasing width in the direction away from the anode electrode in the plan view.

15. The organic light emitting display apparatus of claim 14, wherein the second bank layer includes a micro-protrusion region having a shape that protrudes from the second region and narrows in width in a direction away from the second region in the plan view.

16. A light emitting display apparatus, comprising:
a substrate having a subpixel;
an anode electrode on the substrate in the subpixel;
a bank layer on the substrate and having an opening exposing the anode electrode, the bank layer having a first region and a second region thinner than the first region,
wherein the second region of the bank layer has a shape that protrudes in a direction away from the anode electrode in a plan view.

17. The light emitting display apparatus of claim 16, wherein the second region of the bank layer has a first portion and a second portion protruding away from the anode electrode in different directions from each other in the plan view.

18. The light emitting display apparatus of claim 17, wherein the first portion and the second portion of the second region of the bank layer are spaced apart from each other with the first region of the bank layer disposed between the first portion and the second portion of the second region in the plan view, and
wherein the first region of the bank layer surrounds the second region of the bank layer in the plan view.

19. The light emitting display apparatus of claim 16, wherein the second region of the bank layer has a spearhead shape with a decreasing width in the direction away from the anode electrode in the plan view.

20. The light emitting display apparatus of claim 16, further comprising:
an organic film on the bank layer and the anode electrode; and
another bank layer between the substrate and the bank layer, the other bank layer having an opening that exposes the anode electrode and has a smaller width than the opening of the bank layer,
wherein the organic film covers the first region and the second region of the bank layer and fills the opening of the bank layer and the opening of the other bank layer, and
wherein each of the opening of the bank layer and the opening of the other bank layer has a circular or elliptical shape in the plan view.
